(19) United States
(12) Patent Application Publication
(10) Pub. No.: US 2008/0116447 A1
(43) Pub. Date: May 22, 2008

(54) NON-VOLATILE MEMORY TRANSISTOR WITH QUANTUM WELL CHARGE TRAP

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: Atmel Corporation, San Jose, CA (US)

(21) Appl. No.: 11/561,808

(22) Filed: Nov. 20, 2006

(51) Int. Cl. H01L 29/66; H01L 29/68; H01L 29/78; H01L 21/04

(52) U.S. Cl. 257/24; 438/264; 257/E29.168; 257/E29.17; 257/E21.04

(57) ABSTRACT

Quantum well charge trap transistors are disclosed featuring an ion implanted region below a stack of high-low-high bandgap materials arranged in a sandwich structure. Source and drain electrodes on either side of implanted region, as well as a control gate above the stack allow for electrical control. The implanted region, functioning to provide an offset to the threshold for conduction, is less than feature size F using a technique with spacer masks created for implantation, then removed. The quantum well charge trap stack is built in the area where the spacers were removed with a polysilicon gate atop the stack. Edges of the polysilicon gate are used for self-aligned placement of source and drain.

### TECHNICAL FIELD

The invention relates to non-volatile memory devices and, in particular, to nitride charge trap devices.

### BACKGROUND ART

The ability of thin silicon nitride layers, sandwiched between relatively thick oxide layers to act as charge traps is known. See “A Novel P-Channel Nitride-Trapping Nonvolatile Memory Device with Excellent Reliability Properties” by H. T. Lue et al. in IEEE Electron Device Letters, August 2005, p. 583-585, describing a P-channel nitride trapping device with an ONO gate above “relatively thick tunnel oxide”. Such devices are useful as non-volatile memory units. Unlike conventional SONOS devices, which also have a nitride trap layer, the described devices employ a thicker oxide layer compared to the very thin oxide layer of SONOS devices that is used for tunneling.

In a paper entitled “Fabrication and Program/Erase Characteristics of 30-nm SONOS Nonvolatile Memory Devices” by S. K. Sung et al., the authors describe a SONOS SOI (silicon-on-insulator) non-volatile transistor memory having a 30 nm long and 30 nm wide channel, i.e. smaller in dimensions than can be made with lithography. Such tiny devices are made with a “sidewall patterning technique”.

One of the problems experienced by most prior SONOS devices that rely upon nitride charge trapping is that they rely on sites and energy levels where trapping occurs, such as in bulk nitride, the nitride-oxide interface, or nanocrystals or similar confinement structures.

What is needed are non-volatile memory charge storage devices that have the reliability of nitride trap devices but without specific trap sites and preferably having dimensions that are smaller than can be made with lithography.

### SUMMARY OF INVENTION

A manufacturing method has been devised for nitride trap devices wherein a very thin low bandgap material is an overlayer on a high bandgap material, with another layer of the high bandgap material forming a sandwich that is a quantum well. An ONO sandwich is a preferred example of a high-low-high bandgap combination. The quantum well is charged and discharged using a special implant charge region in charge transfer relation to the quantum well.

The device is formed using spacer windows, of the type described in U.S. Pat. No. 6,624,027 to E. Daemen et al., assigned to the assignee of the present invention, as an implant mask to define a narrow aperture in an SOI wafer, or the like with a planar substrate. Through this aperture a P+ implant region is made into a P-type substrate to establish the charge region. The object is to create a P+ region below the surface of the substrate, forcing charge to reside closer to oxide-nitride interfaces that form a quantum well and not relying on charge trap sites.

After the P+ implant the spacers are removed. The opening is widened by spacer removal. The widened opening is at least the minimum feature size, F, with “feature walls” defining edges of the opening. As a specific dimension, F depends on lithographic equipment, but is scalable to whatever lithographic equipment is available. In modern stepper equipment, F is typically in the range of 40 to 150 nanometers and is forecast to become smaller. F depends on the wavelength of the exposing light multiplied by a resolution factor and divided by the numerical aperture of the lithographic system. The resolution factor depends on several variables in the photolithographic process including the quality of the photoresist used and the resolution enhancement techniques such as phase shift masks, off-axis illumination and optical proximity correction. In the industry, F is a characteristic of particular semiconductor manufacturing equipment that uses photolithography.

Sacrificial oxide is grown as a base oxide on the substrate between the feature walls, followed by a nitride layer and another oxide layer. A polysilicon control gate is built over the ONO structure, i.e. a structure resembling a sandwich of high-low-high bandgap materials on the substrate, then trimmed for self-aligned source and drain formation using sidewalls of the quantum well bandgap structure for self-alignment. The source and drain laterally flank the bandgap structure.

A quantum well charge trap exists within the oxide-nitride interfaces. The control gate and P+ implant communicate to establish a vertical electric field to populate the ONO quantum well with charge in cooperation with voltage applied by source and drain electrodes within the substrate or on the substrate to define a channel therebetween. Charge is trapped not in poorly defined trap sites, but in a quantum well formed by different electron affinities between materials of the stacked structure formed by high-low-high bandgap materials.

### BRIEF DESCRIPTION OF THE DRAWINGS

FIGS. 1-12 are side constructional views for a transistor of the present invention.

FIG. 13 is a side view of the transistor of FIG. 1 illustrating geometric and electrical relationships.

FIG. 14 is a simplified top plan view of the transistor of FIG. 12.

FIG. 15 is a plot of threshold voltage versus current in a non-volatile memory ONO transistor without a P+ substrate implant.

FIG. 16 is a plot of threshold voltage versus current in the transistor of FIG. 12.

FIG. 17 is an energy diagram for a potential well of the transistor of FIG. 12.

### DESCRIPTION OF PREFERRED EMBODIMENT

The present invention utilizes a quantum well for charge trapping by having a low bandgap material, like silicon nitride, aluminum nitride or gallium nitride sandwiched between two layers of materials with a higher bandgap, such as silicon dioxide. Other appropriate materials may be used. The two outer materials need not be the same. A key construction step is placing a P+ implant below the stack of high-low-high bandgap materials in a sandwich arrangement to modify charge distribution in the channel of a transistor using the quantum well structure so that the threshold voltage can be favorably altered.

With reference to FIG. 1, substrate 11 is typically a doped semiconductor p-type wafer suitable for manufacture of MOS devices. The silicon substrate 11 is seen to be coated with a thin layer of gate oxide 15 at least 50 Angstroms thick. A first layer of polysilicon 17 is deposited over the gate oxide layer 15 by vapor deposition to a thickness of approximately 1000 Angstroms, although this dimension is not critical. Over the polysilicon layer 17, another layer of oxide 19 is deposited having a thickness of approximately 50 Angstroms.

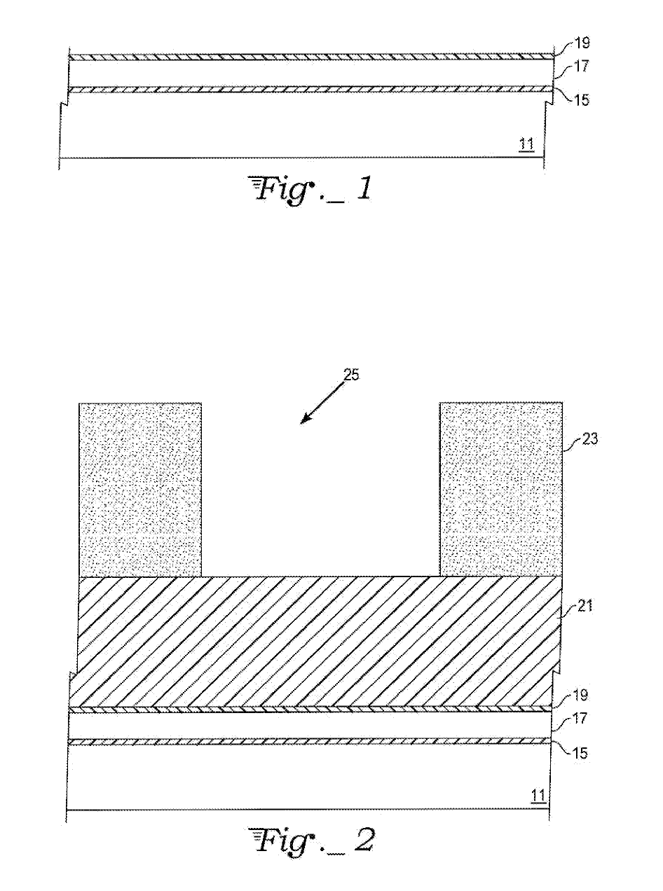

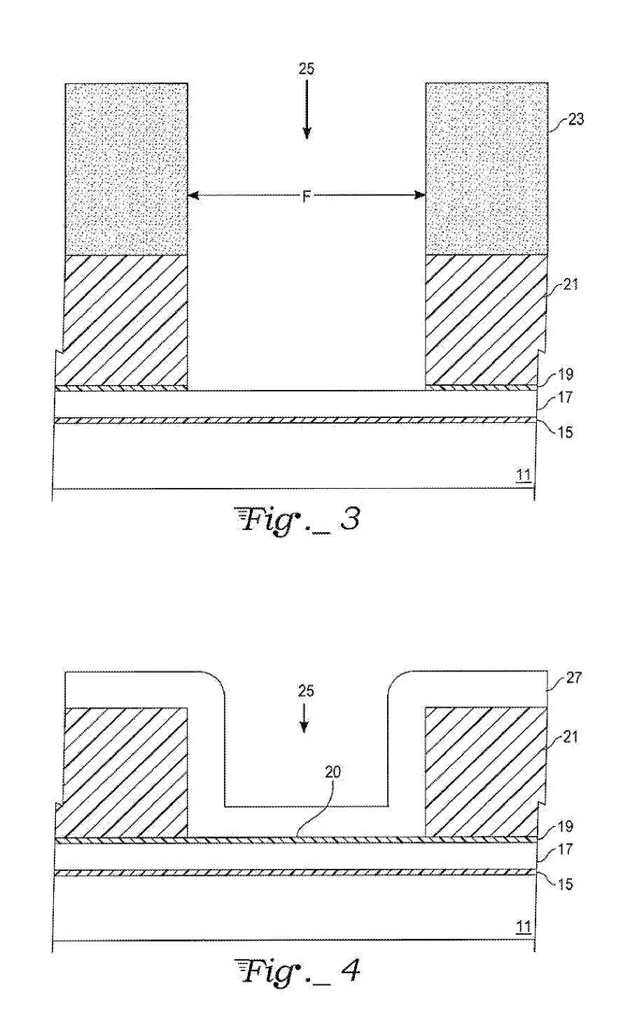

With reference to FIG. 2, over the second layer of oxide 19 an insulative oxide layer 21, preferably a TEOS layer, is deposited having a thickness which is several times the thickness of polysilicon layer 17. It should be noted that the layers 15, 17, 19, and 21 are all planar layers extending entirely across the wafer substrate. Over the TEOS layer 21 a full resist layer 23 is deposited with an opening 25 defined by photolithography and then etched in both the TEOS layer and the resist layer. The opening 25 is ideally the smallest opening that can be defined by a mask, known as the feature size, F. Etching is stopped at upper surface of polysilicon layer 17, meaning that oxide layer is also removed in the opening 25.

After removal of the photoresist, as shown in FIG. 4, a nitride or polysilicon layer 27 is deposited over the TEOS layer 21 with the layer 27 extending down into the opening 25. Prior to deposition of the layer 27 the polysilicon layer 17 may be reoxidized in region 20 so that oxide will separate the nitride or poly layer 27 from polysilicon layer 17.

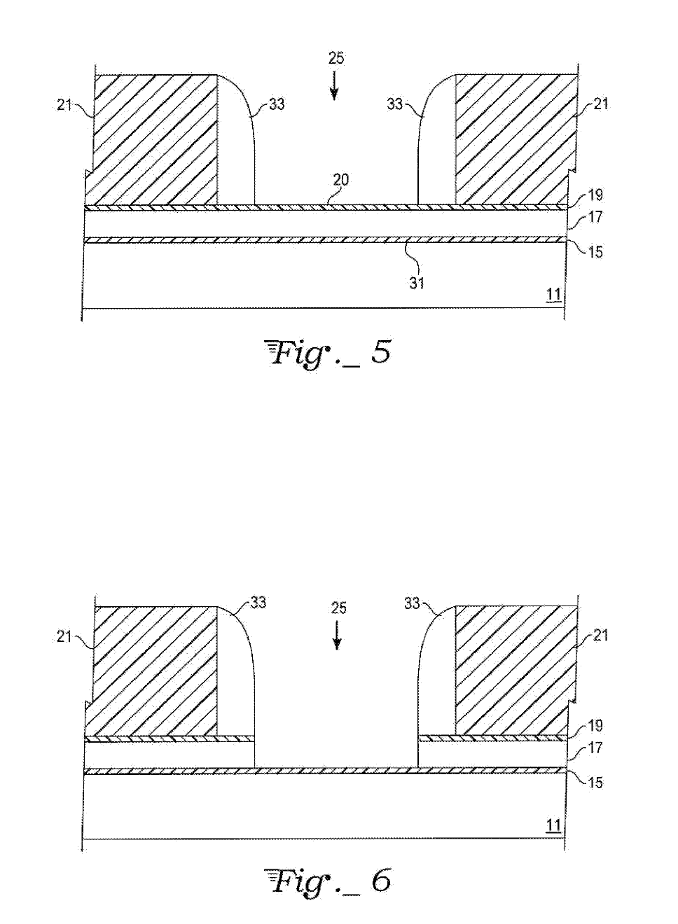

Next, the polysilicon or nitride layer 27 is mostly etched away, except for spacers 33, seen in FIG. 5, which abut side walls formed by opening 25 in the TEOS layer 21. The interior of this opening, i.e. gap, is less than the feature size F. The gap between the spacers is 10 to 50 nm. Further etching between spacers 33 takes the opening 25 to the level of gate oxide layer 15, removing re-oxidized region 20 and polysilicon below this region, as shown in FIG. 6.

With reference to FIG. 7, an ion beam 36 is directed through opening 25 into a shallow depth in substrate 11 to create a P+ region in substrate 11 used for threshold adjustment. The spacers 33 and TEOS layer 21 block the beam from other areas of the substrate and poly layer 17 except where the threshold adjusting charge implanted region 37 is indicated.

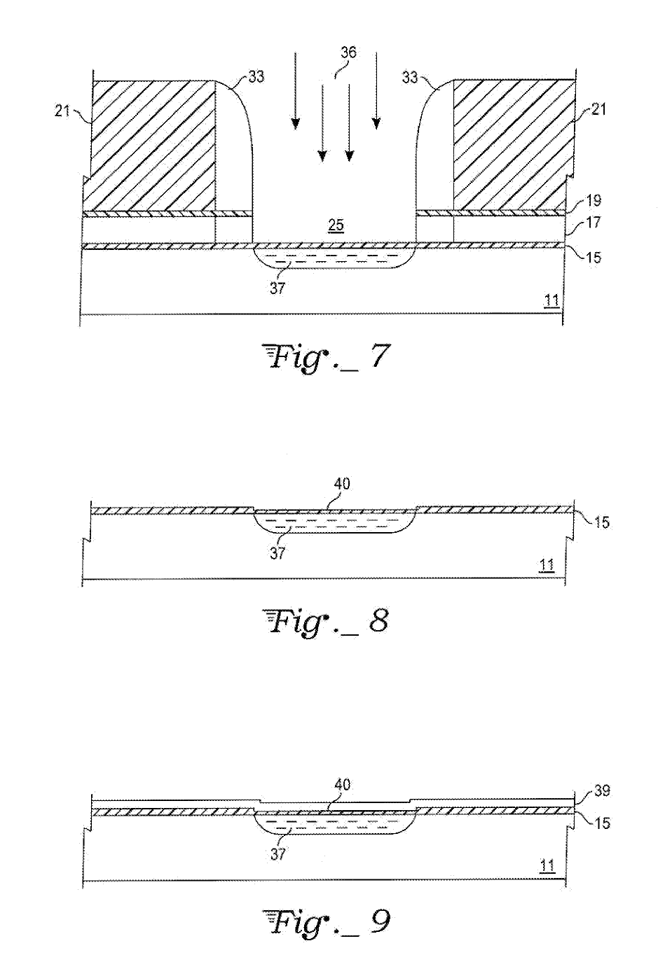

After ion implementation, the center of opening 25 is etched away, as seen in FIG. 7. Then, the remainder of the TEOS layer 21, the spacers 33, oxide layer 19 and poly layer 17 are all removed, leaving only oxide layer 15. The oxide layer 15 is also etched but then reoxidized to form a thin oxide window 40 over the implanted region 37 as a tunnel window, seen in FIG. 8. Such an oxide window has a typical thickness of less than 65 Angstroms but is stepped to provide thicker oxide on lateral sides of the window to block electric fields from source and drain regions.

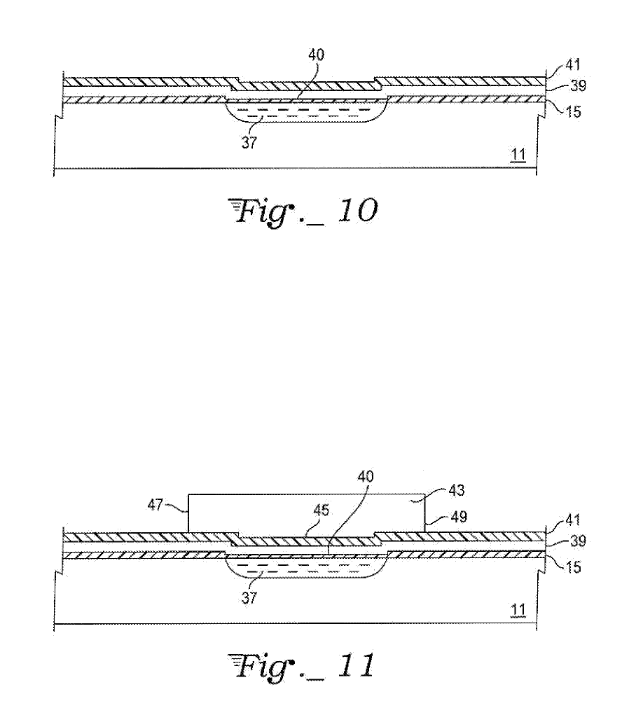

With reference to FIG. 9, a thin nitride overlayer 39 is vapor deposited by CVD or plasma nitride over the oxide layer 15 and oxide window 40 to a thickness of 10-40 nm. Other compatible low bandgap materials forming a high-low-high sandwich, mentioned above, could be used. The nitride deposition follows the contour of the oxide layer 15 which slumps over the threshold adjusting implant region 37 at the oxide window 40. Another oxide layer 41 is deposited over the nitride layer, as seen in FIG. 10. The oxide layer 41 has approximately the same thickness as the thicker portion of oxide layer 15 but may be somewhat thicker. The oxide layers 15 and 41, not including the window layer, are slightly thicker than the low bandgap material.

With reference to FIG. 11, a polysilicon gate layer is deposited over oxide layer 41, then etched in the usual way of a floating gate, with opposed lateral edges 47 and 49, leaving a poly gate 43 symmetrical with the threshold adjusting implant region 37. While poly gate 43 appears similar to a floating gate, with a slumping region 45 over the tunnel window 40 and closer to substrate 11 than other regions of the gate, the poly gate 43 is actually a control gate to be used to control a charge trap formed by the ONO sandwich of layers 15, 39 and 41.

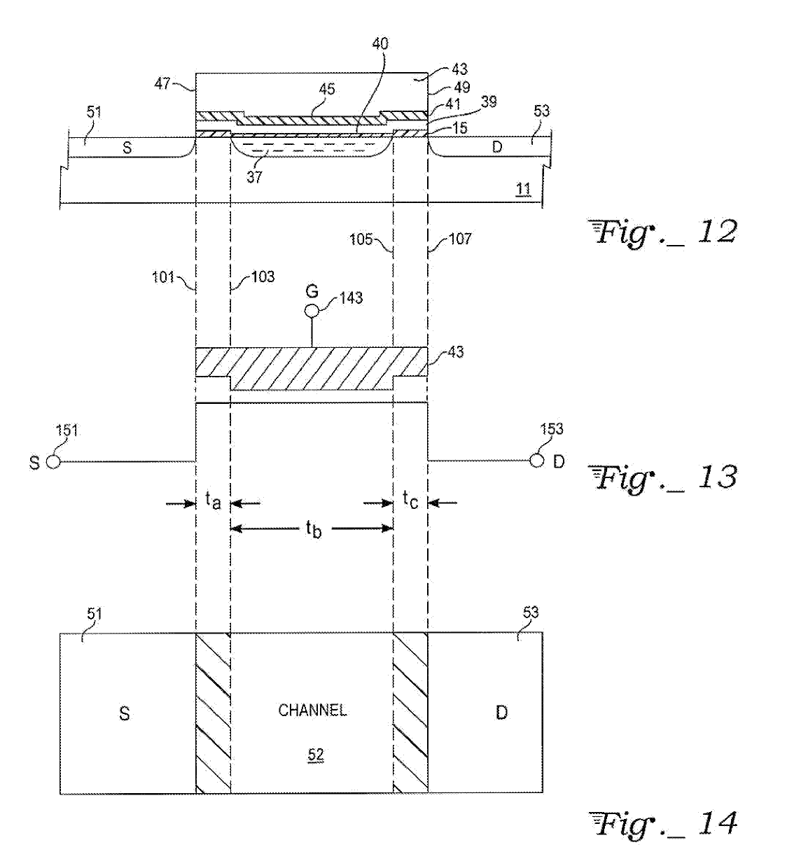

With reference to FIG. 12, the lateral edges 47 and 49 of poly gate 43 are used to self-align placement of source and drain implants 51 and 53 in substrate 11. The source and drain implants have the usual ion concentrations of such electrodes in MOS devices. Formation of source and drain regions completes the transistor structure except for metallization.

In FIG. 13 the source region is represented by electrical terminal 151 and the drain region is represented by electrical terminal 153. The control gate 43 is represented by electrical terminal 143. In FIG. 13, the separation of source 51 from implant region 37 in FIG. 12 is indicated by dashed lines 101 and 103. The separation of the drain 53 from implant region 37 in FIG. 12 is indicated by dashed lines 105 and 107. The dashed lines indicate the lateral dimensions between source and drain on the one hand and the edge of the implant region 37 in FIG. 12 on the other hand. These dimensions are tₐ for the left separation distance, t_{b} for the implant region width and t_{c} for the right separation distance. Note that tₐ=t_{c}.

In the top view of FIG. 14, source region 51 is seen to be spaced apart from drain region 53. A channel region 52 exists between source and drain regions with the threshold adjusting charge implant region 37 of FIG. 12 and the oxide window 40 in the same lateral location. The regions tₐ and t_{c} are shaded. The thicker oxide in these regions reduces problems with high electric fields from the drain region 53 or source region 51 influencing the quantum well charge trap.

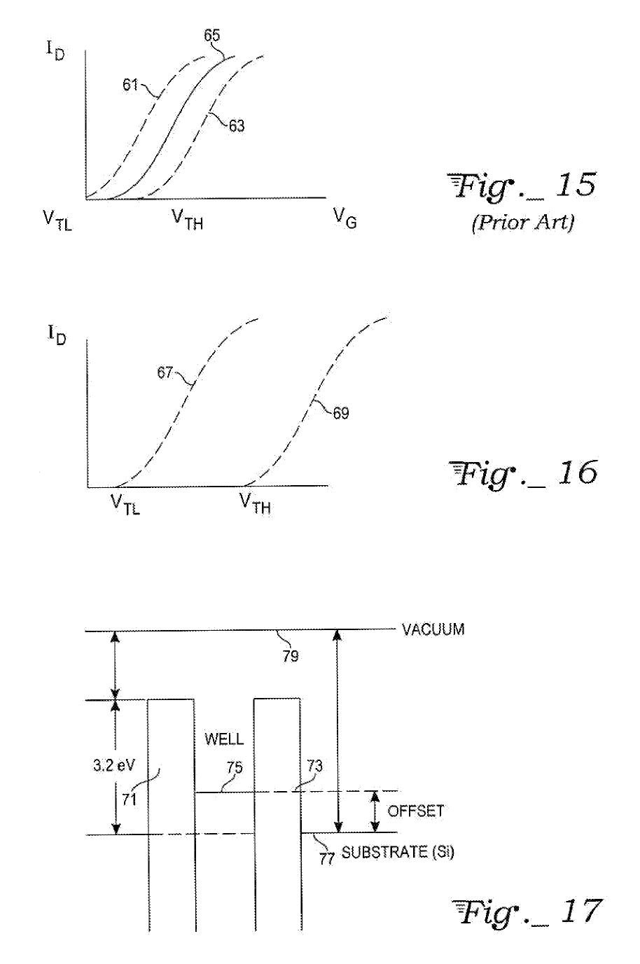

FIG. 15 shows current through a prior art non-volatile memory cell without the implant region 37 of FIG. 12, with spaced apart low threshold voltage, curve 61, and high threshold voltage curve 63 with the sense voltage curve 65 carefully maintained between the two. The low and high threshold voltages are dependent on the state of the charge storage member. On the other hand, a device having the structure of FIG. 12, with an implant region 37, has offset low and high threshold curves 67 and 69 as shown in FIG. 16. Note that the rightward shift of V_{TL} is due to threshold adjusting implant region 37 of FIG. 12. In other words, the implant region 37 situated below the charge storage quantum well pre-sets the low and high thresholds for the transistor. Compare the low voltage conduction threshold V_{TL}, with a charge implant, shown in FIG. 16 to a low voltage threshold V_{TL} without a charge implant, shown in FIG. 15, The P+ implant in region 37 is adjusted by implant dose to increase or decrease the margin of offset between the two sets of curves.

In FIG. 17 the bandgaps of the two oxide layers that sandwich the low bandgap material are symbolized by walls 71 and 73. The bandgap height is approximately 3.2 eV relative to the substrate. The central lower bandgap material is symbolized by level 75 and is about 1 eV and is the bandgap offset between the substrate and the poly attributable to the implant region 37 of FIG. 12. All bandgap values are relative to vacuum level 79. A quantum well is defined by the lower layers 71, 75 and 73 forming a high-low-high sandwich of bandgap materials.

In operation, read, write and erase voltages are similar to NMOS charge trapping non-volatile memory transistors.

1. A non-volatile memory transistor comprising:
a semiconductor substrate having spaced apart source and drain electrodes,
an ion implant region spaced a distance between the source and drain,
a triple layer quantum well over the implant region, and
a control electrode over the quantum well.

2. The memory transistor of claim 1 wherein the triple layer quantum well comprises an ONO charge trap stack having oxide layers less than 65 Angstroms in thickness.

3. The memory transistor of claim 2 wherein the central layer of the stack is a very thin layer compared to the average thickness of the oxide layers.

4. The memory transistor of claim 1 wherein the semiconductor substrate is a wafer substrate.

5. The memory transistor of claim 1 wherein the control electrode is a portion of a polysilicon layer contacting the charge trap stack and having side walls.

6. The memory transistor of claim 1 wherein the source and drain electrodes are regions within the substrate.

7. The memory transistor of claim 5 wherein the source and drain electrodes are aligned with side walls of the control electrode.

8. The memory transistor of claim 1 wherein the ion implant region has a dimension which is less than feature size, F.

9. The memory transistor of claim 1 wherein the ion implant region is a P+ region.

10. A non-volatile memory transistor having a pre-set conduction threshold comprising:
a semiconductor substrate;
a quantum well charge trap over the substrate;
source and drain regions in the substrate flanking the quantum well charge trap;
a control electrode over the quantum well charge trap thereby forming a non-volatile memory transistor; and
a charge implant region means in the substrate below the quantum well for pre-setting the conduction threshold of said memory transistor.

11. The transistor of claim 10 wherein the quantum well charge trap is a high-low-high bandgap material sandwich.

12. The transistor of claim 11 wherein the high-low-high bandgap material sandwich comprises layers of oxide-nitride-oxide (ONO) over the substrate, with an oxide layer contacting the substrate having a step region with a central thin region and peripherally thicker regions proximate to the source and drain.

13. A method of making a non-volatile memory transistor comprising:
establishing a spacer mask on a semiconductor substrate defining an aperture;
implanting a charge region in the substrate through the aperture in the spacer mask;
establishing a tunnel window over the charge region in a first high bandgap material;
removing the spacer mask;
providing a layer of low bandgap material on the high bandgap material;
providing a layer of high bandgap material on the low bandgap material thereby establishing a high-low-high stack of bandgap materials over the charge region thereby forming a quantum well;
providing a control gate over the quantum well, the control gate having lateral edges; and
building source and drain charge regions using lateral edges of the control gate for self-alignment of the source and drain charge regions.

14. The method of claim 13 wherein forming the high-low-high stack comprises depositing oxide, nitride and oxide layers.

15. The method of claim 13 further defined by providing an SOI wafer as a base for establishing the spacer mask.

16. The method of claim 13 further defined by placing spacers of the spacer mask at a distance whereby said aperture has a dimension smaller than feature size, F.

17. The method of claim 13 further defined by creating the control gate to have a dimension that is at least feature size, F.
